(19) United States
(12) Patent Application Publication
(10) Pub. No.: US 2014/0084353 A1
(43) Pub. Date: Mar. 27, 2014

(54) NONVOLATILE SEMICONDUCTOR MEMORY DEVICE

(71) Applicant: KABUSHIKI KAISHA TOSHIBA, Tokyo (JP)

(72) Inventor: Gou FUKANO, Tokyo (JP)

(21) Appl. No.: 13/784,490

(22) Filed: Mar. 4, 2013

(30) Foreign Application Priority Data
Sep. 21, 2012 (JP) 2012-208668

(51) Int. Cl. H01L 29/78

(52) U.S. Cl. CPC H01L 29/78
USPC 257/314

(57) ABSTRACT

A nonvolatile semiconductor memory device with a first region including a memory cell array of a plurality of memory cells arrayed in three dimensions and a second region with a peripheral circuit for controlling the memory cell array is described. The peripheral circuit includes an insulating film and a template region. The template region has a length and a width and the insulating film is spaced from (does not overlap) the edges of the template region and is arranged in the template region so that a coverage ratio of the template region is at least above a minimum coverage ratio of 30-50%. Satisfying the minimum coverage ratio allows the device layers above the second region to be formed with sufficient flatness to allow the memory device to be functional.

### CROSS-REFERENCE TO RELATED APPLICATION(S)

This application is based upon and claims the benefit of priority from Japanese Patent Application No. 2012-208668, filed on Sep. 21, 2012, the entire contents of which are incorporated herein by reference.

### FIELD

An embodiment relates generally to the configuration of a peripheral circuit in a nonvolatile semiconductor memory device.

### BACKGROUND

In recent years, a laminated type semiconductor memory in which memory cells are laminated has been developed. This semiconductor memory allows realization of a high capacity semiconductor memory at low cost.

A peripheral circuit for controlling the semiconductor memory is configured by combining N-MOS transistors and P-MOS transistors. Generally, a template for N-MOS transistors, P-MOS transistors, and the like, are created in advance and then a predetermined circuit pattern is formed by combining these template structures.

### BRIEF DESCRIPTION OF THE DRAWINGS

FIG. 1 illustrates an example of an overall configuration of a nonvolatile semiconductor device according to a first embodiment.

FIG. 2 illustrates an example of a planar configuration of a memory cell array and a peripheral circuit according to the first embodiment.

FIG. 3 illustrates an example of a cross-sectional configuration of the memory cell array and the peripheral circuit according to the first embodiment.

FIG. 4 illustrates an example of a cross-sectional configuration of the memory cell array according to the first embodiment.

FIG. 5 illustrates a perspective view of the memory cell array and the peripheral circuit according to the first embodiment.

FIG. 6 illustrates an example of a planar configuration of a template according to the first embodiment.

FIGS. 7A-7C illustrate another example of a planar configuration of a template according to the first embodiment.

FIG. 8 illustrates another example of a planar configuration of a template according to the first embodiment.

FIGS. 9A and 9B illustrate another example of a planar configuration of a template according to the first embodiment.

FIGS. 10A and 10B illustrate another example of a planar configuration of a template according to the first embodiment.

FIGS. 11A and 11B illustrate another example of a planar configuration of a template according to the first embodiment.

FIGS. 12A and 12B illustrate another example of a planar configuration of a template according to the first embodiment.

FIG. 13 illustrates an example of a planar configuration of a template having a guard ring according to the first embodiment.

FIG. 14 illustrates another example of a planar configuration of a template having a guard ring according to the first embodiment.

FIG. 15 illustrates another example of a planar configuration of a template having a guard ring according to the first embodiment.

FIGS. 16A-16C illustrates an example of a planar configuration, a cross-sectional view, and a circuit diagram of a template according to a second embodiment.

FIG. 17 illustrates an example of a planar configuration of a template according to a third embodiment.

FIG. 18 illustrates an example of a planar configuration of a template according to a modified example of the third embodiment.

### DETAILED DESCRIPTION

In the present disclosure, a nonvolatile semiconductor memory device is described which has a region in which a contact plug capable of connecting with a signal line and a power source line is arranged while a minimum coverage ratio for an insulating film (e.g., 30-50%) is satisfied, the insulating film being arranged above the peripheral circuit with a thickness corresponding to the height of the memory cell array. A nonvolatile semiconductor memory device comprises a first region in which a memory cell array including memory cells arrayed in three dimensions has been formed. The device further includes a second region in which a peripheral circuit controlling the memory cell array has been formed. The second region includes an insulating film and a template, wherein, when, in the plane, the template has a length of V1 in the first direction and a length of H1 in the second direction and the insulating film has a length of DY_V1 in the first direction and a length of DY_H1 in the second direction, the first region is provided outside the insulating film and inside the template in the plan, and the insulating film is arranged in the template in such a manner that a coverage ratio DY_V1·DY_H1/H1·V1 of the insulating film with respect to the template is equal to or above a minimum coverage ratio. The minimum coverage ratio is about 30-50% and represents the value sufficient to allow layers to be formed above the second region with a flatness sufficient to allow the memory device to function.

In the following, the present embodiment is explained with reference to the drawings. In the following explanation, throughout all the drawings, common parts are indicated using common reference numerals. However, it should be noted that the drawings are schematic, and the relationship between a thickness and planar dimensions, the proportion of the thickness of each layer, and the like are generally different from actual dimensions and relative dimensions. Therefore, the specific thickness and dimensions should be determined by taking into consideration the following explanation.

In the following examples of a nonvolatile semiconductor memory device contain a memory cell array and a peripheral circuit controlling the memory cell array, the formation of a region is explained in which a contact plug capable of connecting with a signal line and a power source line is arranged while a minimum coverage value of an insulating film is satisfied, the insulating film being arranged above the peripheral circuit at a position corresponding to the height of the memory cell array.

### First Embodiment

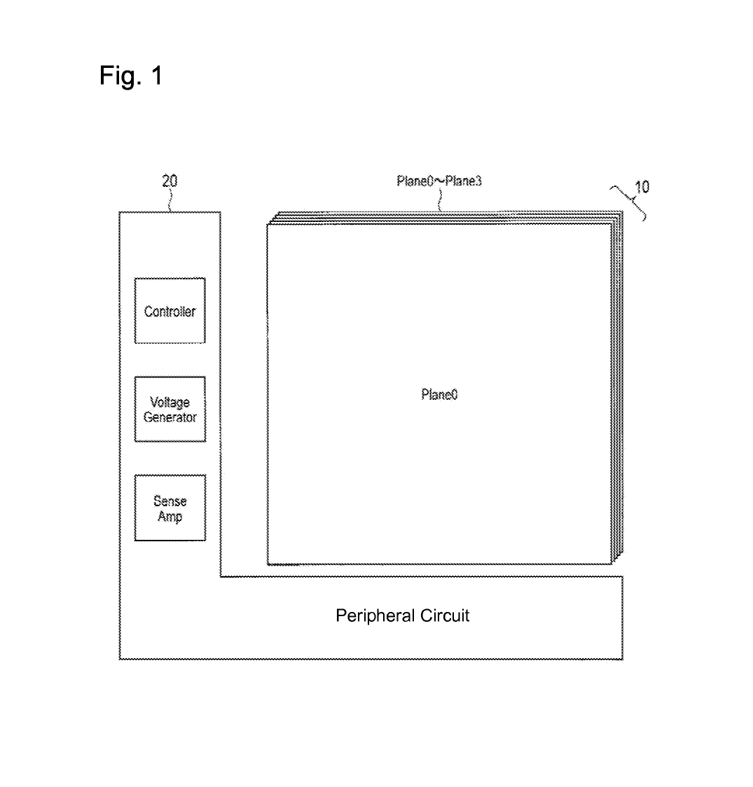

FIGS. 1-15 illustrate a nonvolatile semiconductor memory device according to a first embodiment.

As illustrated in FIG. 1, the nonvolatile semiconductor memory device according to the first embodiment is configured from a memory cell array 10 (for example, the array includes plane 0-plane 3 as depicted in the drawing) and a peripheral circuit 20 capable of controlling the memory cell array 10.

Each of the plane 0-plane 3 is capable of holding data and is provided with a plurality of laminated type memory cells MC formed in a direction normal to a semiconductor substrate.

The peripheral circuit 20 is configured by a control part controlling the plane 0-plane 3, a voltage generating circuit outputting various voltages when data writing, reading, erasing, and the like are performed, and a sense amplifier that performs data reading, writing, etc. These are configured by various MOS transistors (for example, those of a high breakdown voltage and of a low breakdown voltage) and signal lines and contact plugs CP that supply voltages to the MOS transistors. These MOS transistors, signal lines, contact plugs CP and the like are also arranged under the memory cell array 10.

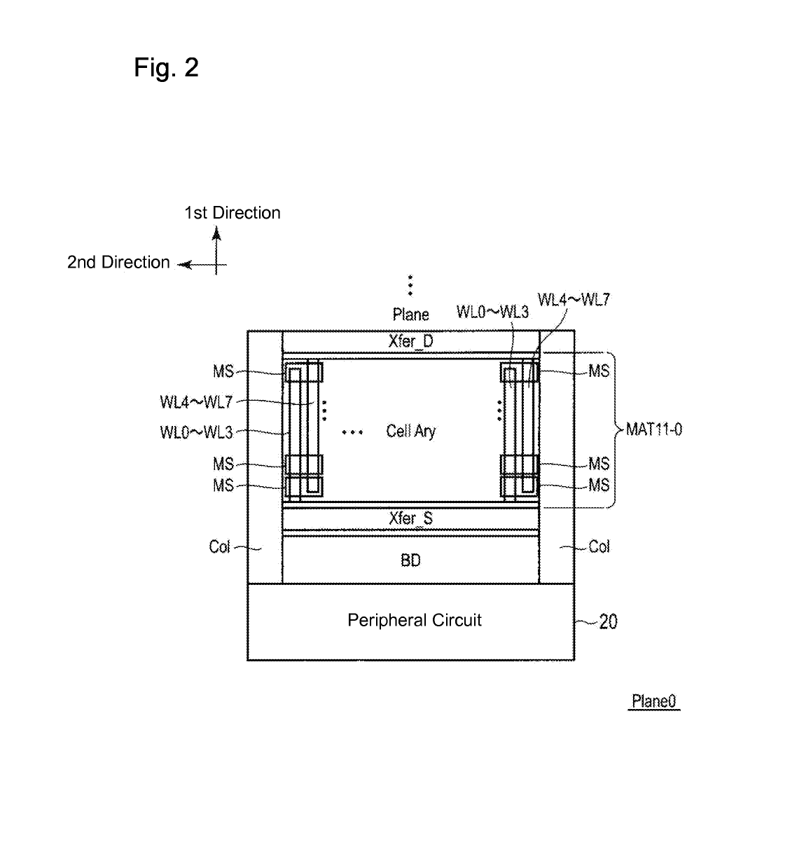

Next, a plan view of the plane 0 is illustrated using FIG. 2. The plane 1-plane 3 have the same configuration as the plane 0 and therefore their explanation is omitted.

As illustrated in the drawing, the plane 0 is provided with an MAT11_0, an XFER_S and an XFER_D (transfer circuits) arranged with MAT11_0 between them, a column decoder COL (COL in the drawing), and a block decoder BD (BD in the drawing).

The MAT11_0 is provided with a plurality of memory strings MS. In a manner penetrating through these memory strings MS, word lines WL0-WL3 (referred to as the first signal line group in the following) and word lines WL4-WL7 (referred to as the second signal line group in the following) are formed extending in a first direction, and a plurality of bit lines BL (not illustrated in the drawings) are formed extending in a second direction.

One end of the word lines WL0-WL3 is connected to the XFER_S and one end of the word lines WL4-WL7 is connected to the XFER_D. That is, the word lines WL that penetrate through the MAT11 are arranged in a comb shape.

The XFER_D and the XFER_S are configured from a plurality of MOS transistors and select one of the memory strings MS in the MAT11-0. Specifically, upon receiving a control signal from the block decoder BD, the XFER_D and the XFER_S are capable of selecting a memory string MS as a read, write or erase operation target.

The block decoder BD switches the MOS transistors in the XFER_S and the XFER_D on and off and thereby selects a memory string MS for a write, read or erase operation target from a plurality of memory strings MS.

The column decoder COL selects a bit line BL (not illustrated in the drawings).

<Simplified Cross-Sectional View of Memory Cell Array 10 and Peripheral Circuit 20>

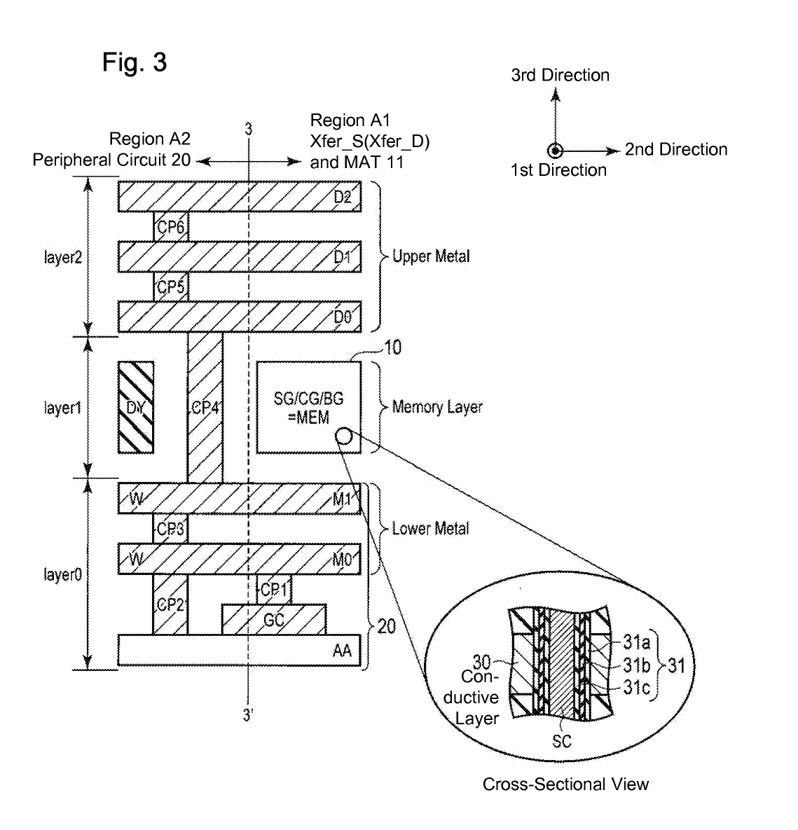

A cross-sectional view of the memory cell array 10 and the peripheral circuit 20 is divided into the layer 0-layer 3 and is briefly explained using FIG. 3. As illustrated in FIG. 3, with a line 3-3′ as a boundary, a cross-sectional view of the peripheral circuit 20 is illustrated on a left side and a cross-sectional view of the XFER_S (XFER_D) and the MAT11 is illustrated on a right side.

<Layer 0 (Signal Line M0)>

As described above, in the nonvolatile semiconductor memory device according to the present embodiment, an MOS transistor that configures a portion of the peripheral circuit 20, and MOS transistors that comprise the XFER_D (or XFER_S), and the like are formed directly under the memory cell array 10. Specifically, at a lowest layer, a control gate GC is formed on an active region AA that is formed in a semiconductor substrate (not illustrated in the drawing), and, in a manner sandwiching the control gate GC, impurity diffusion layers (source and drain) are provided, thereby forming an MOS transistor.

A contact plug CP1 is formed on the control gate GC, and a contact plug CP2 is formed on the impurity diffusion layer AA. Upper ends of the contact plugs CP1 and CP2 are respectively connected to signal lines M0 (strictly speaking, different signal lines M0).

Specifically, the signal line M0 connecting to the contact plug CP2 of which a lower end is connected to the impurity diffusion layer has a function of supplying a voltage (for example, VDD) for driving the MOS transistor.

On the other hand, the signal line M0 connecting to the contact plug CP1 of which a lower end is connected to the control gate GC has a function of providing a voltage to the control gate GC and controlling ON and OFF states of the MOS transistor.

Next, a contact plug CP3 is formed on the signal lines M0, and a signal line M1 that is orthogonal to the signal lines M0 is formed on the contact plug CP3. The signal line M1 has a function of supplying voltages VDD and VSS and transmitting a signal from the impurity diffusion layer that functions as a source terminal of the MOS transistor.

<Layer 1 (Signal Line M1)>

The MAT11 and a portion of the XFER_S (XFER_D) are formed on a region A1 side above the signal line M1 and an insulating film DY is formed on a region A2 side above the signal line M1. In the MAT11, a plurality of semiconductor layers SC are formed in a matrix form (along a first direction and second direction). These semiconductor layers SC are formed extending in a direction (third direction) generally perpendicular to device substrate.

At a region where a semiconductor layer SC is formed, word lines WL that are formed along the second direction are formed in a plurality of layers toward the third direction. That is, at a region of an intersection point of a word line WL and a semiconductor layer SC, a memory cell MC is formed.

An enlarged cross-sectional view of the memory cell MC is illustrated on a right side in FIG. 3. As illustrated in the drawing, a gate oxide film 31c, a charge storage layer 31b, and a blocking layer 31a are sequentially formed from the surface of the semiconductor layer SC in a manner covering the surface of the semiconductor layer SC. Further, a conductive layer 30 is formed in a manner covering the surface of the blocking layer 31a.

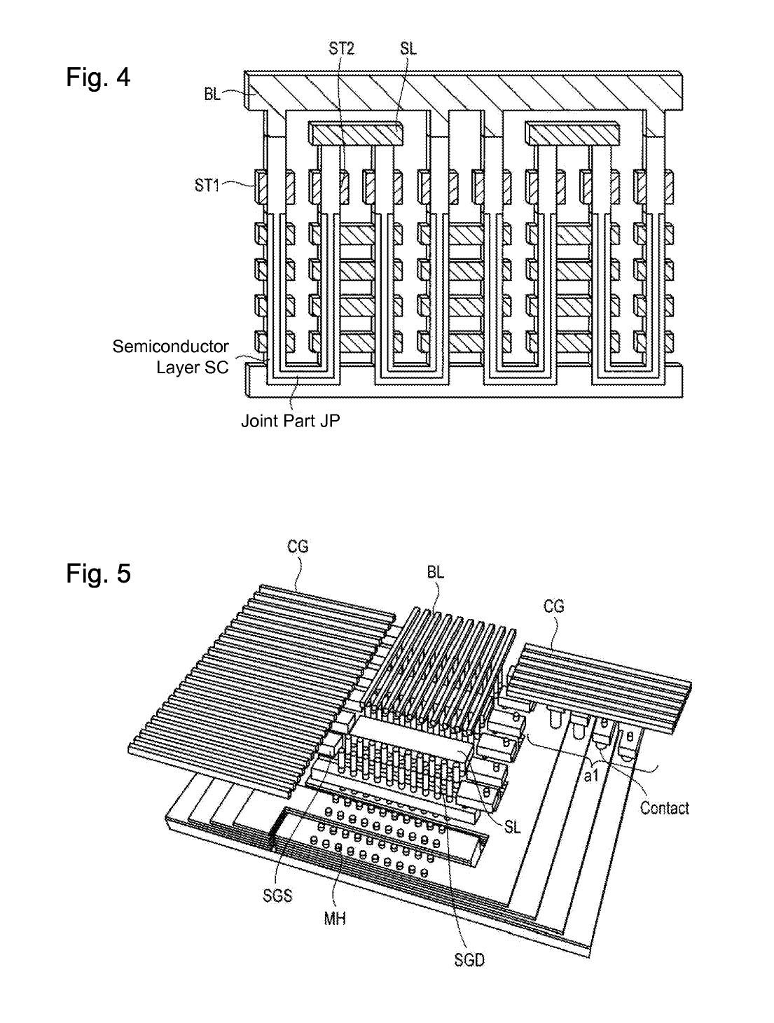

Further, as illustrated in FIG. 4, mutually adjacent semiconductor layers SC are joined via a joint part JP. That is, the semiconductor layers SC that mutually adjacent to each other form a U-shaped memory string MS via the joint part JP. One end of the memory string MS is connected via a selection transistor ST1 to a bit line BL that is formed along the second direction, and the other end of the memory string MS is connected via a selection transistor ST2 to a source line SL.

Further, as illustrated in FIG. 5, one word line WL is commonly connected to gates of corresponding memory cells MC of NAND strings among a plurality of NAND strings. Therefore, when viewed from top, the word lines WL are formed in a comb shape. A contact plug CP connected to one end of the word lines WL is arranged in a region a1 where the XFER_S is formed.

Voltage supply and the like are performed via the contact plug CP.

Referring back to FIG. 3, the explanation of the layer 1 is continued. As illustrated in the drawing, an insulating film DY having a height of about the same as that of the MAT11 in the region A1 is formed in the region A2. The MAT11 is not formed in the region A2. As a result, if this insulating film DY is not provided, the flatness of upper layers in the region A2 cannot be maintained.

<Layer 2 (Signal Line D0)>

A signal line D0 is formed above the MAT11 and the insulating film DY, and a contact plug CP5 is formed on the signal line D0. A signal line D1 is further formed on an upper end of the contact plug CP5, and a signal line D2 is formed on a contact plug CP6 that is formed on the signal line D1.

In the case of the nonvolatile semiconductor device according to the first embodiment, a position of the insulating film DY is arranged on a template (to be explained in the following), and then, the MOS transistor of the layer 0, the contact plugs CP that connect with the layer 2 and the layer 0, and the like are formed.

<Plan View of Region A2>

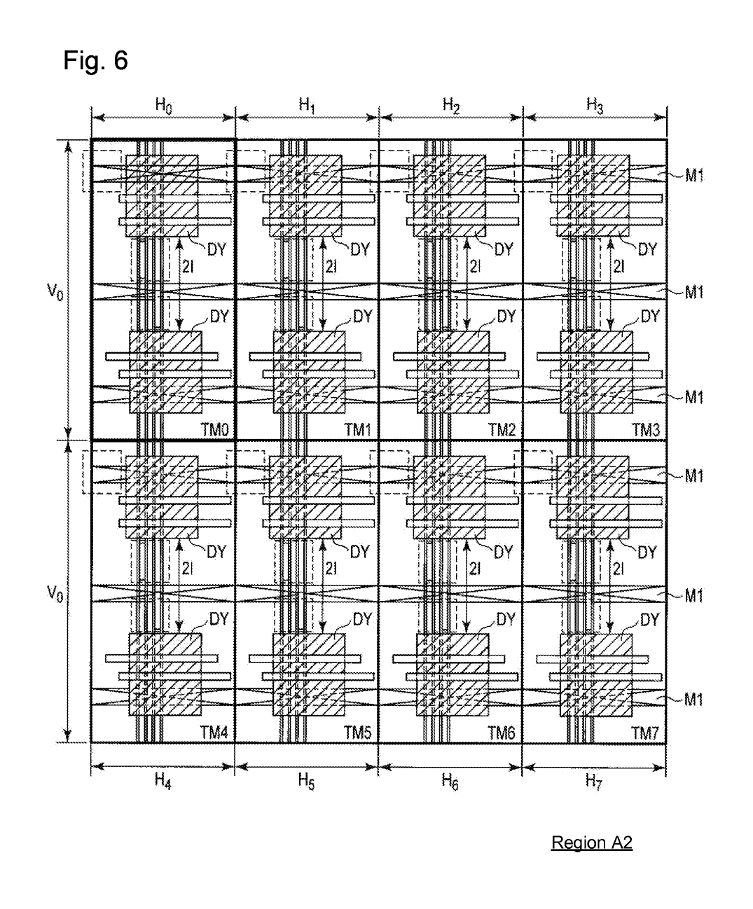

Next, a plan view of the above-described region A2 is illustrated using FIG. 6. As illustrated in the drawing, templates TM0-TM7, for example, are arranged in the region A2. These templates TM0-TM7 have the same height V0 in a vertical direction (as viewed on the page). However, there is no particular restriction on the widths of the templates TM0-TM7 in a lateral direction (indicated as H0, H1, H2, H3 . . . in the drawing). When a template has a large width, a plurality of insulating films DY may be arranged in the lateral direction, and when a template has a narrow width, an insulating film DY may be shared by a plurality of templates. However, since the depicted templates have the general same configuration the template TM0 (surrounded by a thick frame in the drawing) is explained.

As illustrated in the drawing, the template TM0 has a height of V0 and a width of H0. In the template TM0, the above-described insulating film DY, signal lines M0 and M1, and the like are formed. Two insulating films DY, for example, are arranged in the template TM0. These insulating films DY (which will now be referred to as DY1 and DY2) are arranged a distance 21 apart from each other. As will be described later, the region between the insulating films DY1 and DY2 is a region for arranging a contact plug CP4 that connects a MOS transistor that is configured under the insulating films DY1 and DY2 and a signal line D0 that is formed above the insulating films DY1 and DY2. The distance 21 between the insulating films DY1 and DY2 is at least a distance that allows the contact plug CP4 to be arranged.

Further, shapes of the insulating films DY and relative positions of the insulating films DY with respect to the template TM0 are determined so that the following conditions are satisfied.

(A) Coverage of the insulating films DY with respect to the template TM0 is equal to or above a minimum coverage. The minimum coverage may be expressed as a ratio, fraction, or percentage of the template area.

(B) When the insulating films DY are arranged in the template TM0, an empty (blank) first region exists inside the template TM0 but outside the insulating films DY.

Here, the minimum coverage means a minimum percentage of the template area covered by the insulating films DY that allows the flatness of upper layer wirings above the insulating films DY in the region A2 to be maintained. That is, when the coverage of the insulating films DY with respect to the template TM0 is below the minimum coverage, the flatness of the upper layer wirings of the insulating films DY cannot be maintained. More specifically, when the coverage of the insulating films DY with respect to the template TM0 is below the minimum coverage, a partial recess may occur in the upper layer wirings at a portion of the upper layer wirings such as the signal lines D0 and D1 corresponding to a region between the first insulating film DY1 and the second insulating film DY2 that is adjacent to the first insulating film DY. The signal line D0 and the signal line D1 may be short-circuited or opened by the partial recess of the upper layer wirings.

In other words, satisfying the condition (A) means a problematic partial recess does not occur in the upper layer wirings above the insulating films DY.

The condition (B) is also explained.

The condition (B) is a condition for providing a region for arranging the contact plug CP4 inside the template TM0 but outside the insulating films DY. The blank first region in this embodiment may be in any area between an outer edge of the insulating film DY and the outer edge of the template TM0.

In the condition (B), it is defined as for “when the insulating films DY are arranged in the template TM0.” However, the condition (B) is not limited to this case. For example, in the case where one insulating film DY is arranged in the templates TM0-TM3, the condition (B) is deemed to be replaced by “(B) when the insulating film DY is arranged in the templates TM0-TM3, a blank first region exists inside the entire templates TM0-TM3 and outside the insulating film DY.” In order to satisfy conditions (A) and (B), the insulating films DY1 and DY2 generally have a shape of a square or a rectangle (a cube or a cuboid when viewed in multiple dimensions). In this context, “cuboid” includes both a cube shape and rectangular parallelepiped and “rectangular” includes a square shape.

The space between four sides of the insulating film DY and the outer edge of the template TM0 is also a region for arranging the contact plug CP4 that connects the MOS transistor formed in the layer 0 and the signal line D0 formed in the layer 2.

Next, a plan view of each layer in the region A2 is illustrated. Same as in the above, the explanation is given with a focus on the template TM0.

<Plan View of Template TM0>

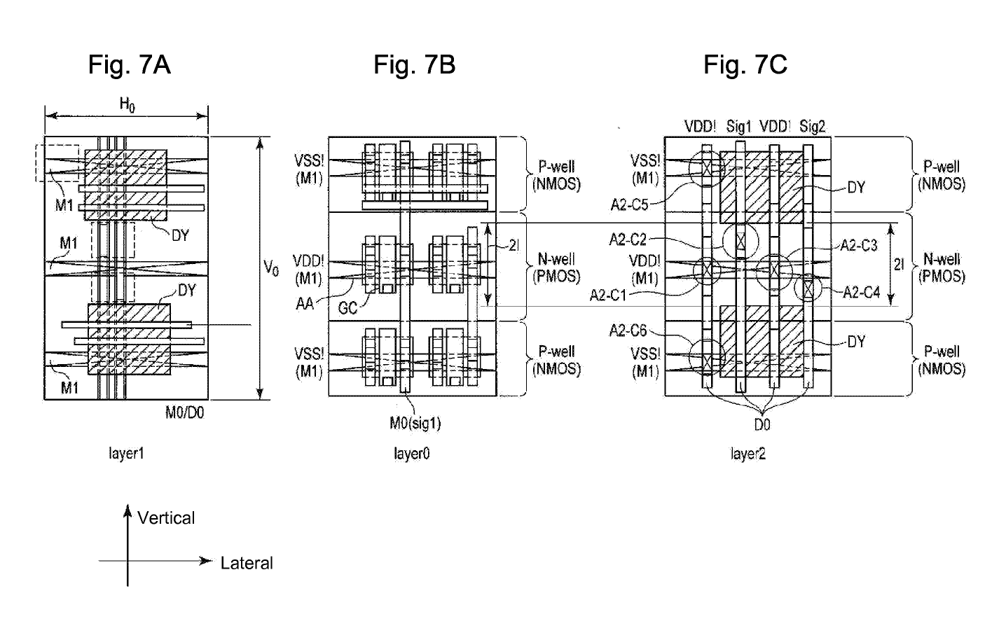

Plan views of the layer 0-layer 2 of the template TM0 are illustrated using FIG. 7A-FIG. 7C. FIG. 7A illustrates a plan view focusing on the layer 1 in which the above-described insulating films DY1 and DY2 are formed. FIG. 7B illustrates a plan view focusing on the layer 0 and illustrates various MOS transistors formed on the semiconductor substrate. FIG. 7C illustrates a plan view focusing on the layer 2 and illustrates how the contact plug CP4 that connects the signal line M1 and the signal line D0 in the space of the distance 21 between the adjacent insulating films DY1 and DY2. FIG. 7A has been described in the above and therefore its explanation is omitted.

<FIG. 7B>

As illustrated in FIG. 7B, in the layer 0, a P-well layer and an N-well layer are formed on the semiconductor substrate, and various MOS transistors are formed on these wells. For example, an N-type MOS transistor is formed on the P-well layer and a P-type MOS transistor is formed on the N-well layer.

The signal line M0 that is electrically connected to the impurity diffusion layer (source or drain) that functions as a part of the MOS transistors is arranged in the longitudinal direction of the paper, and the signal line M1 is arranged above the signal line M0 in the lateral direction of the paper. As described above, the signal line M1 supplies to the impurity diffusion layer (input terminal) that functions as a drain the voltage VDD (for example, 1.8 V) and the voltage VSS (for example, the ground potential) (in the following, the signal line M1 that is illustrated in the drawing is also referred to as the power source line M1).

Further, although not illustrated in FIG. 7B, another signal line M1 is further arranged in a manner parallel to the above-described power source line M1. This signal line M1 is electrically connected to the impurity diffusion layer (output terminal) that functions as a source. Next, the contact plug CP4 that connects to the signal line M1 is formed on the N-well layer in the range of the distance 21, and is subsequently electrically connected to the signal line D0 in the layer 2.

<FIG. 7C>

Next, the plan view of the layer 2 is explained using FIG. 7C. As illustrated in the drawing, region A2_C1-region A2_C4 are provided in the space of the distance 21 between the adjacent insulating films DY1 and DY2.

The contact plug CP4 that is electrically connected to the impurity diffusion layer of the MOS transistor illustrated in FIG. 7B is arranged in the region A2_C1-region A2_C4. That is, the region A2_C1-region A2_C4 are regions where the impurity diffusion layer of the MOS transistor and the signal line D0 are connected in the order of, from the lower layers, signal line M0=>contact plug CP3=>signal line M1=>contact plug CP4=>signal line D0.

In the region A2_C2 and the region A2_C4, the signal line M1 having a length equivalent to the width of the signal line D0 is arranged in the lateral direction in a manner overlapping with the signal line D0. In other words, the signal line M1 having a length equal to the width of the signal line D0 is arranged in the lateral direction of the paper.

Similarly, also in a region A2_C5 and a region A2_C6, the impurity diffusion layer (source) of the MOS transistor and the signal line D0 are electrically connected. That is, the impurity diffusion layer of the MOS transistor and the signal line D0 are connected in the order of, from the lower layers, signal line M0=>contact plug CP3=>signal line M1=>contact plug CP4=>signal line D0.

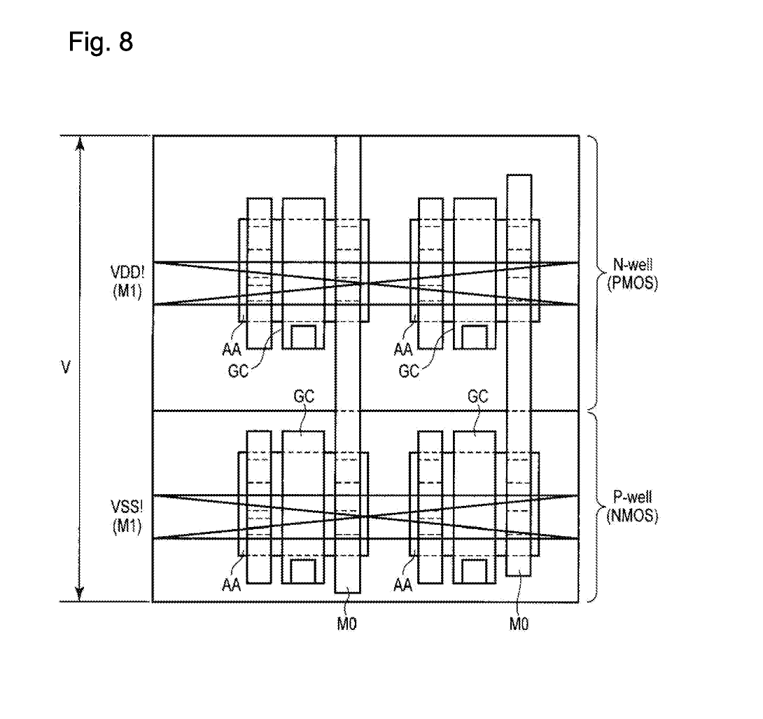

In FIG. 7A-FIG. 7C, as an example, the explanation is given using the template TM in which P-well layers are formed on two ends of the N-well layer in the template height V0. The present invention is not limited to this. The template TM may also be configured by an N-well layer and a P-well layer. This template TM arrangement is illustrated in FIG. 8.

FIG. 8 illustrates a template TM configured by an N-well layer and a P-well layer. In the case of a template TM as illustrated in FIG. 8, for example, an insulating film DY is arranged at a center of the template TM. This allows a space to be provided between the insulating film DY and the outer edge of the template TM.

The template TM illustrated in FIG. 8 may have a height V that is the same as the height of the template TM illustrated in the above-described FIG. 7A-FIG. 7C, that is, V0. The height V may also be half of V0 (V0/2), and may also be other values.

<Various Templates TM and Coverage of Insulating Film DY>

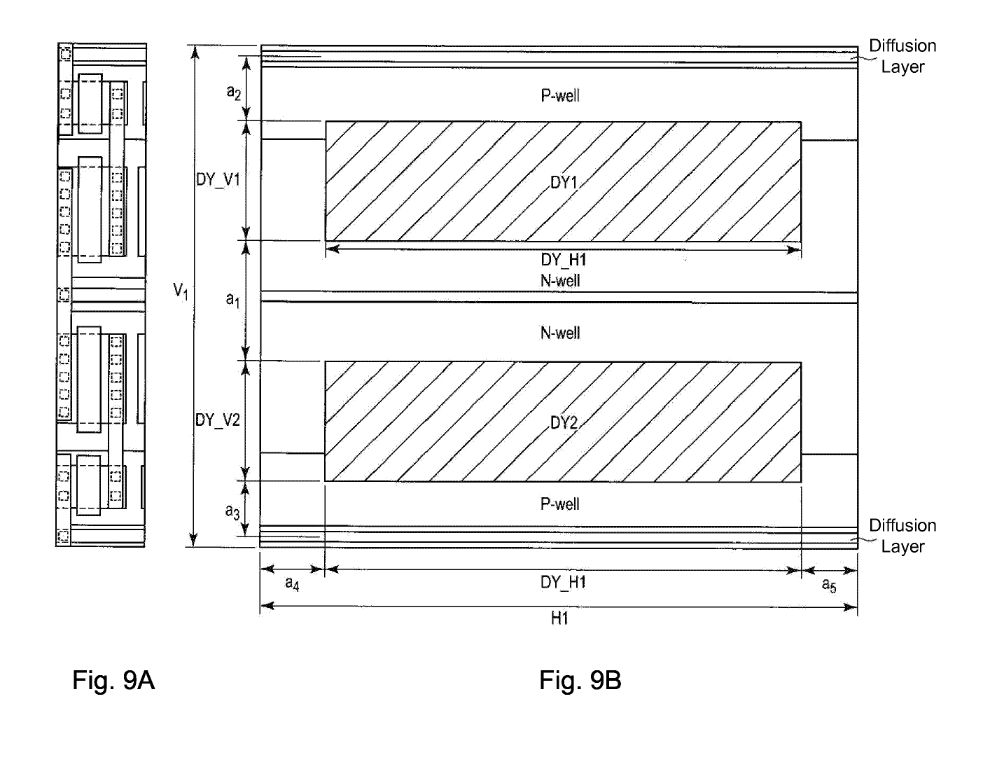

Next, various templates TM are illustrated using FIG. 9-FIG. 15, and coverage of an insulating film DY provided in a template TM is explained.

<First Template TM>

FIG. 9A and FIG. 9B illustrate plan views of a first template TM. FIG. 9A illustrates a plan view of an MOS transistor provided in the layer 0, and is, for example, the template TM illustrated in the above-described FIG. 7C. Here, a template TM for a low-breakdown-voltage MOS transistor is illustrated. An actual circuit layout in which a plurality of transistors of FIG. 9A are arranged corresponds to the width of FIG. 9B. For the purpose of explanation, FIG. 9B illustrates only P-wells (or N-wells), diffusion layers and insulating films.

FIG. 9B illustrates a plan view with a focus on the layer 1. As illustrated in the drawing, the template TM has a height of V1 and a width of H1. In the case where there are a plurality of templates, the height V1 is the same for all the templates, but the width H1 depends on each circuit.

Next, the insulating films DY1 and DY2 are respectively arranged in the template TM are arranged in such a manner that the distance 21 between the adjacent insulating films DY1 and DY2 is 21=a1, and distances between four sides of each of the insulating films DY1 and DY2 and outer edges of the template TM are a2-a5 and heights and widths of the insulating films DY1 and DY2 are respectively DY_Vi and DY_Hi, where i=1 and 2.

In this case, coverage x1 occupied by both the insulating films DY1 and DY2 with respect to the area of the template TM is expressed by the following formula (1).

coverage x1=ΣDY_{—}Vi·DY_{—}Hi/H1·V1 (1)

In order to maintain the flatness of the above-described region A2 (the region where the peripheral circuit 20 is formed), it is required that the value of the coverage x1 expressed by the formula (1) is equal to or greater than a minimum coverage x_min. That is, when the coverage x1 obtained from the formula (1) is below the value of the minimum coverage x_min, it is possible that the flatness of the region A2 cannot be maintained. The numerator in the above formula (1) expresses a sum of the area of the insulating film DY1 and the area of the insulating film DY2, that is, (DY_V1·DY_H1+DY_V2·DY_H2).

The height V1 of the template TM and the distance 21 between the adjacent insulating films DY1 and DY2 are constants. Therefore, it is necessary to set the height, width and arrangement position of each of the insulating films DY so that the formula (1) satisfies the minimum coverage x_min.

When the distance between the insulating films DY1 and DY2 is a0, the following relations between a0 and a2-a5 are satisfied: a2+a3>a0; and a4+a5>a0. These relational expressions are similarly satisfied in the following embodiments.

<Second Template TM>

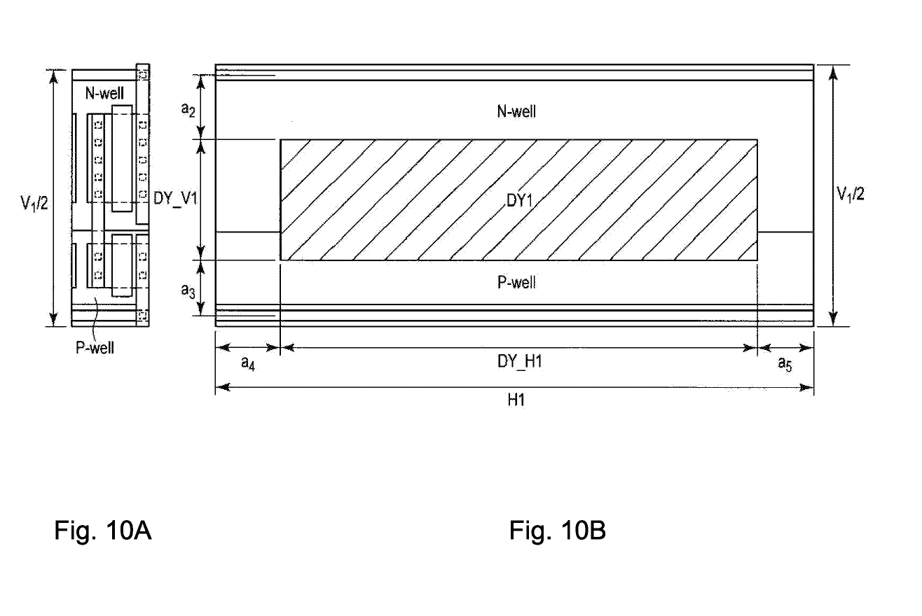

Next, plan views of a second template TM is illustrated using FIG. 10A and FIG. 10B. The template TM illustrated in FIG. 10A and FIG. 10B has a size half of the above-described first template TM. That is, the template TM has a height of V1/2 and a width of H1.

An insulating film DY1 that is the same as in the above-described FIG. 9A and FIG. 9B is arranged in this template TM. The condition for the arrangement of the insulating film DY1 is the same as in the above, and the coverage of the insulating film DY1 that is a condition for the second template TM is also the same as the above formula (1).

<Third Template TM>

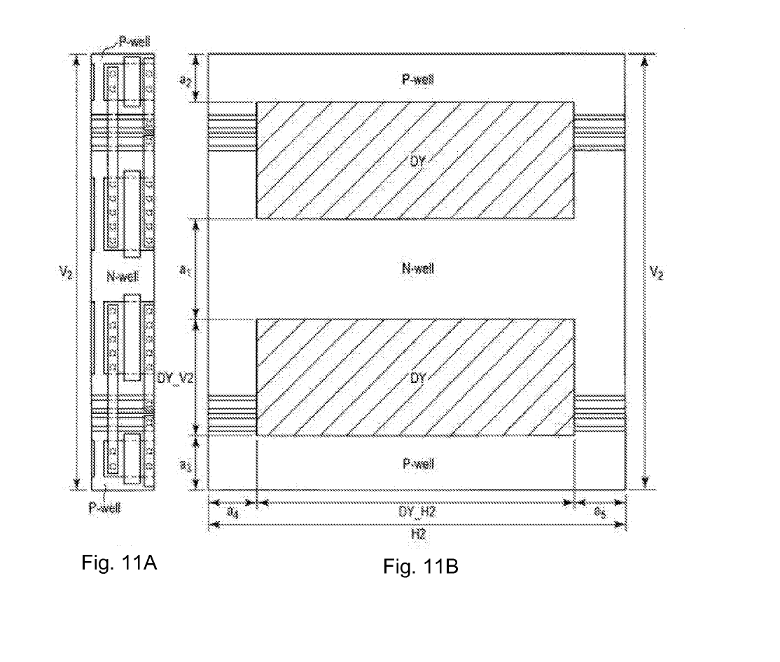

Next, a third template TM is explained using FIG. 11A and FIG. 11B. Arrangement and coverage of insulating films DY in the third template TM are explained for a case where a so-called guard ring is used in the template TM, that is, for example, an N/P-type MOS transistor group (where “/” indicates “or”) (which may include only one N/P-type MOS transistor) is surrounded by an N/P-well layer in the layer 0 in which the MOS transistors are formed.

FIG. 11A illustrates a plan view of the layer 0. As illustrated, a P-type MOS transistor group (including six P-type MOS transistors) that is provided on an N-well layer is surrounded by a P-well layer. Similarly, an N-type MOS transistor group that is provided on a P-well layer is surrounded by an N-well layer. Here, the coverage of the insulating films DY in the case of such a third template TM is explained. The template TM of FIG. 11A has a height of V2/2 and a width of H2. In the case where there are a plurality of templates, the height V2 is the same for all the templates, but the width H2 depends on each circuit.

FIG. 11B illustrates a plan view of the layer 1 in the case where the third template TM is adopted. As illustrated in the drawing, the third template TM has a height of V2 and a width of H2. In the third template TM, the insulating films DY1 and DY2 have heights of DY_Vi and widths of DY_Hi, where i=1 and 2.

The insulating films DY1 and DY2 are respectively arranged in the third template TM under the following condition. Specifically, the insulating films DY1 and DY2 are arranged in such a manner that the distance 21 between the adjacent insulating films DY1 and DY2 is 21=a1, and distances between four sides of each of the insulating films DY1 and DY2 and outer edges of the template TM are a2-a5 and heights and widths of the insulating films DY1 and DY2 are respectively DY_Vi and DY_Hi, where i=1 and 2.

In this case, coverage x2 occupied by both the insulating films DY1 and DY2 with respect to the area of the third template TM is expressed by the following formula (2).

coverage x2=ΣDY_{—}Vi·DY_{—}Hi/H2·V2 (2)

In order to maintain the flatness of the above-described region A2 (the region where the peripheral circuit 20 is formed), it is required that the coverage x2 expressed by the formula (2) is equal to or greater than a minimum coverage x_min. As described above, this is for maintaining the flatness of the region A2 (the region where the peripheral circuit 20 is formed). That is, when the coverage obtained from the formula (2) is below the minimum coverage x_min, it is possible that the flatness of the region A2 cannot be maintained. The numerator in the above formula (2) expresses a sum of the area of the insulating film DY1 and the area of the insulating film DY2, that is, (DY_V1·DY_H1+DY_V2·DY_H2).

The height V2 of the template TM and the distance 21 between the adjacent insulating films DY1 and DY2 are constants. Therefore, the height, width and arrangement position of each of the insulating films DY are set so that the formula (2) satisfies the minimum coverage x_min.

<Fourth Template TM>

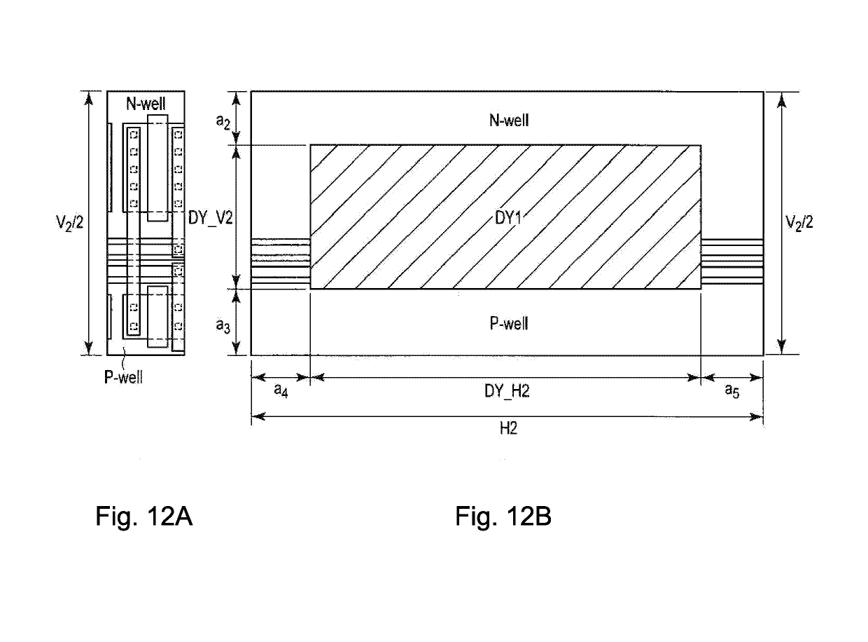

Next, a fourth template TM is explained using FIG. 12A and FIG. 12B. FIG. 12A and FIG. 12B illustrate plan views of a template TM having a size half of that of the above-described third template TM. That is, the template TM has a height of V2/2 and a width of H2. In the case where there are a plurality of templates, the height V2/2 is the same for all the templates, but the width H2 depends on each circuit.

An insulating film DY1 that is the same as in FIG. 11A and FIG. 11B is arranged in this template TM. The condition for the arrangement of the insulating film DY1 is the same as in the above, and the coverage of the insulating film DY1 that is a condition for the fourth template TM is also the same as the above formula (2). That is, the insulating film DY1 is arranged having distances a2-a5 between four sides of the insulating film DY1 and outer edges of the template TM, and height DY_Vi and width DY_Hi, where i=1.

<Fifth Templates TM>

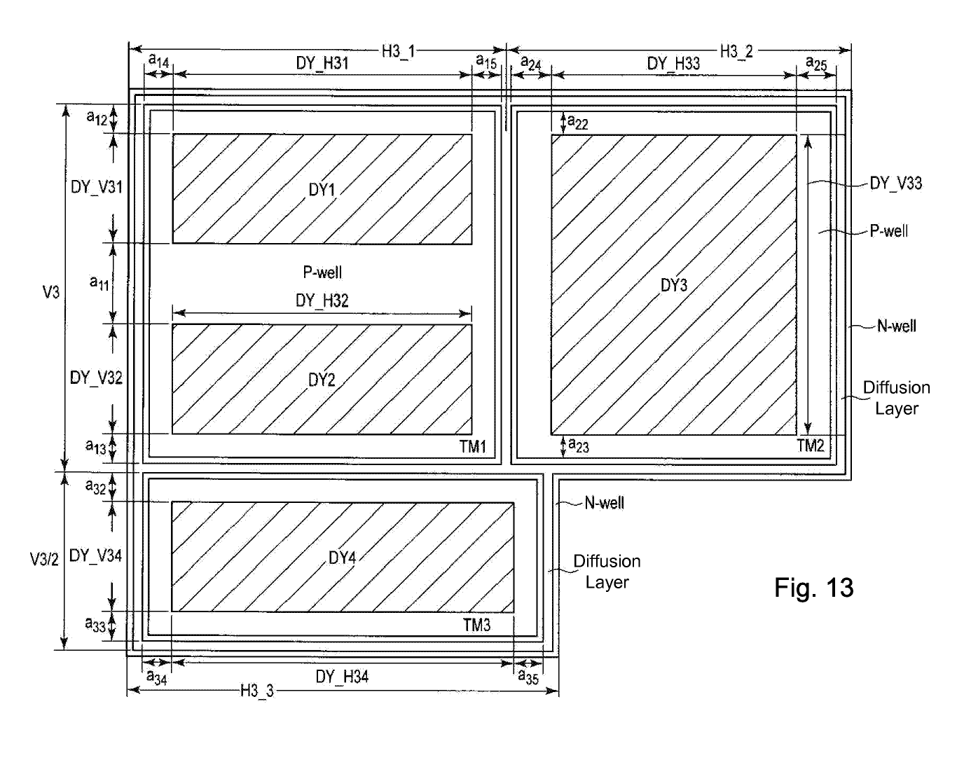

Next, fifth templates TM1-TM3 are explained using FIG. 13. Similar to the above-described third template TM, the fifth templates TM1-TM3 illustrated in FIG. 13 are templates TM in which, for example, a guard ring is formed around an N/P-well by, for example, a P/N-well.

The fifth templates TM1-TM3 are templates that mainly function as capacitors. That is, a capacitor is configured by an MOS transistor in the layer 0. Here, a template having a size half of that of the fifth template TM1 is also described.

<Fifth Template TM1>

As illustrated, the fifth template TM1 has a height of V3 and a width of H3_1. Similar to the above, in the fifth template TM1, heights (DY_V31, DY_V32), widths (DY_H31, DY_H32) and arrangement positions of both the insulating film DY1 and the insulating film DY2 are set in such a manner that the minimum coverage x_min with respect to the fifth template TM1 is satisfied while satisfying the distance 21=a11 between the insulating film DY1 and the insulating film DY2, and distances a12-a15 between four sides of each of the insulating films DY1 and DY2 and a surrounding diffusion layer.

<Fifth Template TM2>

Next, the fifth template TM2 is explained. The fifth template TM2 has a height of V3 and a width of H3_2. Similar to the above, in the fifth template TM2, a height (DY_V33), a width (DY_H33) and an arrangement position of the insulating film DY3 are set in such a manner that the minimum coverage x_min with respect to the fifth template TM2 is satisfied while satisfying distances a22-a25 between four sides of the insulating film DY3 and a surrounding diffusion layer.

<Fifth Template TM3>

Further, the fifth template TM3 is explained. The fifth template TM3 has a height of V3/2 and a width of H3_3. Similar to the above, in the fifth template TM3, a height (DY_V34), a width (DY_H34) and an arrangement position of the insulating film DY4 are set in such a manner that the minimum coverage x_min with respect to the fifth template TM3 is satisfied while satisfying distances a32-a35 between four sides of the insulating film DY4 and a surrounding diffusion layer.

The height of the fifth template TM3 is half of that of the fifth template TM1. Therefore, the height DY_V34 of the insulating film DY4 may be the same as the height of one of the insulating film DY1 and the insulating film DY2.

When the width H3_1 and the width H3_3 are the same, the width of the insulating film DY4 can also be the same as the width of the insulating films DY1 and DY2.

Further, in the case where there are a plurality of templates TM, the widths H3_1, H3_2 and H3_3 have different values corresponding to respective circuits.

<Sixth Templates TM>

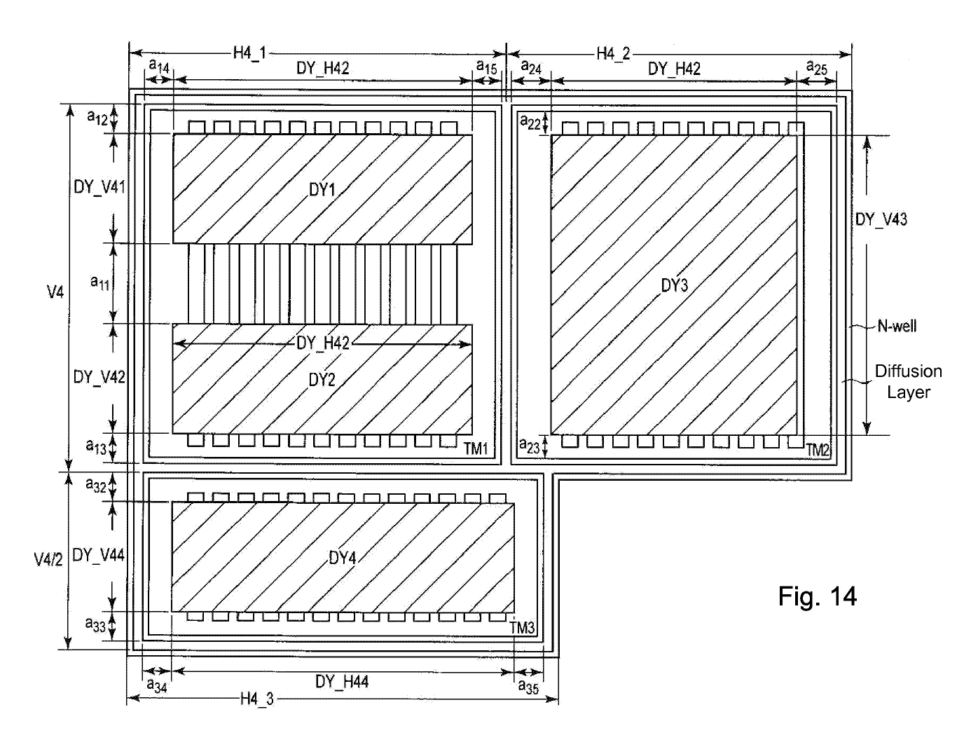

Next, sixth templates TM1-TM3 are explained using FIG. 14. Similar to the above-described third template TM, the sixth templates TM1-TM3 illustrated in FIG. 14 are templates TM surrounding each of which a guard ring is formed by, for example, a P/N-well.

The sixth templates TM1-TM3 are templates that mainly function as device resistors. That is, a resistor is configured by a plurality of MOS transistors in the layer 0. Here, a template (the sixth template TM3 in the drawing) having a size half of that of the sixth template TM1 is also described.

<Sixth Template TM1>

As illustrated in the drawing, the sixth template TM1 has a height of V4 and a width of H4_1. Similar to the above, in the sixth template TM1, heights (DY_V41, DY_V42), widths (DY_H41, DY_H42) and arrangement positions of both the insulating film DY1 and the insulating film DY2 are set in such a manner that the minimum coverage with respect to the sixth template TM1 is satisfied while satisfying the distance 21=a11 between the insulating film DY1 and the insulating film DY2, and distances a12-a15 between four sides of each of the insulating films DY1 and DY2 and a surrounding diffusion layer.

<Sixth Template TM2>

Next, the Sixth template TM2 is explained. The sixth template TM2 has a height of V4 and a width of H4_2. Similar to the above, in the sixth template TM2, a height (DY_V43), a width (DY_H42) and an arrangement position of the insulating film DY3 are specified in such a manner that the minimum coverage x_min with respect to the sixth template TM2 is satisfied while satisfying distances a22-a25 between four sides of the insulating film DY3 and a surrounding diffusion layer.

<Sixth Template TM3>

Further, the sixth template TM3 is explained. The sixth template TM3 has a height of V4/2 and a width of H4_3. Similar to the above, in the sixth template TM3, a height (DY_V44), a width (DY_H44) and an arrangement position of the insulating film DY4 are set in such a manner that the minimum coverage x_min with respect to the sixth template TM3 is satisfied while satisfying distances a32-a35 between four sides of the insulating film DY4 and a surrounding diffusion layer.

The height of the sixth template TM3 is half of that of the sixth template TM1. Therefore, the height DY_V44 of the insulating film DY4 may be the same as the height of one of the insulating film DY1 and the insulating film DY2.

When the width H4_1 and the width H4_3 are the same, the width of the insulating film DY4 is also the same as the width of the insulating films DY1 and DY2.

Further, in the case where there are a plurality of templates TM, the widths H4_1, H4_2 and H4_3 have different values corresponding to respective circuits.

<Seventh Templates TM>

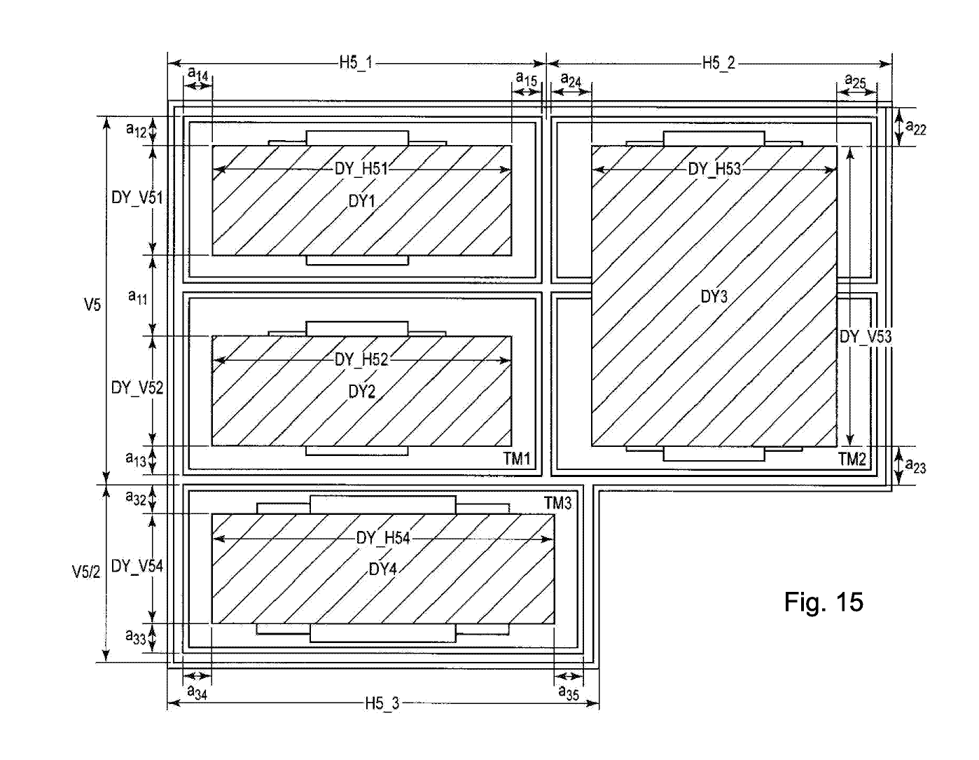

Next, seventh templates TM1-TM4 are explained using FIG. 15. Similar to the above-described third template TM, the seventh templates TM1-TM4 illustrated in FIG. 15 are templates TM in which, for example, a guard ring is formed around an N/P-well by, for example, a P/N-well.

The seventh templates TM1-TM3 are templates TM for forming high-breakdown-voltage MOS transistors. Here, a template (the seventh template TM4 in the drawing) having a size half of that of the seventh template TM1 is also described.

<Seventh Template TM1>

As illustrated, the seventh template TM1 has a height of V5 and a width of H5_1. Similar to the above, in the seventh template TM1, heights (DY_V51, DY_V52), widths (DY_H51, DY_H52) and arrangement positions of both the insulating film DY1 and the insulating film DY2 are set in such a manner that the minimum coverage x_min with respect to the seventh template TM1 is satisfied while satisfying the distance 21=a11 between the insulating film DY1 and the insulating film DY2, and distances a12-a15 between the insulating films DY1 and DY2 and a surrounding diffusion layer.

<Seventh Template TM2>

Next, the seventh template TM2 is explained. As illustrated, the seventh template TM2 has a height of V5 and a width of H5_2. Similar to the above, in the seventh template TM2, a height (DY_V53), a width (DY_H53) and an arrangement position of the insulating film DY3 are set in such a manner that the minimum coverage x_min with respect to the seventh template TM2 is satisfied while satisfying distances a22-a25 between the insulating film DY3 and a surrounding diffusion layer.

<Seventh Template TM3>

Next, the seventh template TM3 is explained. The seventh template TM3 has a height of V5/2 and a width of H5_3. Similar to the above, in the seventh template TM3, a height (DY_V54), a width (DY_H54) and an arrangement position of the insulating film DY3 are set in such a manner that the minimum coverage with respect to the seventh template TM3 is satisfied while satisfying distances a32-a35 between the insulating film DY3 and a surrounding diffusion layer.

The height of the seventh template TM3 is half of that of the seventh template TM1. Therefore, the height DY_V54 of the insulating film DY5 may be the same as the height of one of the insulating film DY1 and the insulating film DY2.

When the width H5_1 and the width H5_3 are the same, the width of the insulating film DY4 is also the same as the width of the insulating films DY1 and DY2.

### Effects According to First Embodiment

According to the nonvolatile semiconductor device of the first embodiment, the following effects (1)-(5) can be obtained.

(1) Flatness of an upper layer in the region A2 can be maintained.
For example, consider arranging an insulating film DY in a plurality of templates TM of equal height, well type, arrangement position and width. In this case, according to the first embodiment, the arrangement of the insulating film DY relative to each of the templates TM can be uniformly performed, and as a whole, the insulating film DY is arranged in a certain pattern.

In the nonvolatile semiconductor device according to the first embodiment, the position of the insulating film DY is determined in advance, and thereafter, MOS transistors and contact plugs CP are formed. Therefore, the insulating film DY can be arranged in a manner that the minimum coverage condition expressed by the above formula (1) or formula (2) is satisfied. Therefore, flatness of an upper layer in the region A2 can be maintained.

(2) While achieving the above effect (1), a region in which a contact plug CP is provided can be sufficiently provided.
The reason for this is as follows. As described in the above, in the case of the nonvolatile semiconductor device according to the first embodiment, the insulating film is divided, and the adjacent insulating film DY1 and insulating film DY2 having a distance 21 therebetween are arranged before the contact plugs CP. As a result, the contact plug CP3 can be arranged in the region of the distance 21.

For example, as illustrated in FIG. 7C and others, this allows the contact plugs CP capable of connecting the layer 0 and the layer 2 to be arranged in the region A2_C1 through region A2_C4. That is, in the case of the nonvolatile semiconductor device according to the first embodiment, while improving the flatness of the upper layer (effect (1)), a region in which a contact plug CP is provided can be secured.

(3) Ease of design can be improved.
In the case of the nonvolatile semiconductor device according to the first embodiment, the position of the insulating film DY is determined in advance, and thereafter, MOS transistors and contact plugs CP are formed. Therefore, even when templates having the same height and same well arrangement type are combined with respect to the insulating film DY, an amount of space in each region can be easily recognized.

That is, not only a sufficient region for arranging a contact plug CP can be secured, since the region has regularity, when connecting the layer 0 and the layer 2, the region can be easily understood, thereby facilitating design.

4) Electrostatic capacitance can be reduced.
In the case of the nonvolatile semiconductor device according to the first embodiment, the arrangement pattern of the insulating film DY is uniform. Therefore, variation in electrostatic capacitance between the insulating film DY and the contact plug CP3 can be suppressed.

In the following, for explaining the effects of the first embodiment, as an example, a comparative example is explained. In a nonvolatile semiconductor device according to the comparative example, a layer 0 is first formed and then a contact plug CP in a layer 1 is formed. Thereafter, an insulating film DY is formed.

That is, in the case of a template TM according to the comparative example, the insulating film DY is provided in accordance with the arrangement of the contact plug CP. In other words, the insulating film DY is provided in the space around the contact plug CP. Therefore, the shape of the insulating film DY depends on the contact plug CP.

Therefore, depending on the region, the distance between the insulating film DY and the contact plug CP may be short in some region and long in some other region. Therefore, variation in the electrostatic capacitance may occur in some places, causing instability in the device as a whole.

However, in the case of the nonvolatile semiconductor device according to the first embodiment, the insulating film DY is first formed, and thereafter the MOS transistor in the layer 0 and the signal line connecting to the MOS resistor are formed. The same applies to the contact plug CP that connects the layer 0 and the layer 2. The insulating film DY is arranged in a predetermined region in the template TM. Therefore, as illustrated in FIG. 7C, the region where the contact plug CP is arranged is determined. That is, the electrostatic capacitance between the templates TM can be made uniform, and as a whole, the occurrence of a region where the electrostatic capacitance is especially high can be suppressed. In this way, in the case of the nonvolatile semiconductor device according to the first embodiment, reduction in the electrostatic capacitance can be suppressed.

(5) Voltage drop can be prevented.
As illustrated in FIG. 8, the signal line M1 supplying the voltage VDD is positioned near the center of the template TM. Therefore, the voltage supplied to the signal line M0 of the layer 0 via the contact plug CP near the center (regions A2_C1-A2_C5 in FIG. 7C) is supplied from the vicinity of the center of the template TM to the MOS transistor positioned in the vertical direction of the paper.

That is, as compared to the case where voltage is supplied at one end of the template TM to, for example, a signal line M0 and the like to drive, for example, an MOS transistor positioned on the other end of the template TM, the distance to an MOS transistor formed in the template TM is short. Therefore, during the voltage supplying process, the voltage does not drop and the operation does not become unstable.

### Second Embodiment

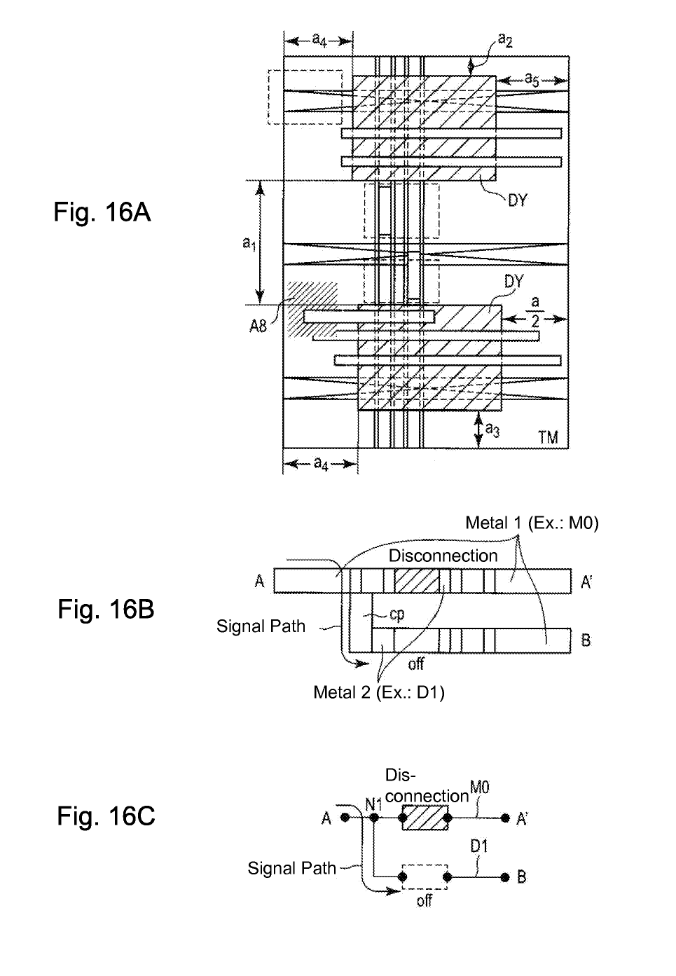

Next, a nonvolatile semiconductor device according to a second embodiment is explained using FIG. 16A-FIG. 16C. In the second embodiment, circuit layout is designed in a manner allowing two or more ways of connection in a particular wiring. After an operation test of a chip, in a case where it is operationally better to switch a signal from a predetermined connection to a different connection, a new mask for a layer to be modified is created and the chip is re-fabricated from that layer without the need of changing the whole fabrication process.

Therefore, fabrication time and cost can be reduced. Further, in the nonvolatile semiconductor device according to the present embodiment, since fabrication time is long and cost is high for fabricating a memory cell array from Si, when modification is necessary, it is desirable that the modification be performed at a layer above, for example, the signal line D0. Therefore, even when the signal line to be switched is positioned at a lower part of the cell array, such as in the case of the signal line M0, the signal line can be raised to, for example, the signal line D1 by using a contact plug. In this case, only the signal line D1, the contact plug CP6, and the signal line D2 need to be modified.

FIG. 16A illustrates a plan view of a nonvolatile semiconductor device according to the second embodiment, in which insulating films DY1 and DY2 are arranged in a template TM.

FIG. 16B illustrates an enlarged view in a cross-sectional direction of a region A8 in FIG. 16A. FIG. 16C illustrates a circuit diagram of FIG. 16B.

As illustrated in FIG. 16A, for example, assume that a disconnection occurs in the region A8 in a signal line M0 (A-A′ line in FIG. 16B) formed in a layer 0. In this case, as illustrated in FIG. 16B, an alternative path is formed using, for example, a signal line D1 via a contact plug CP connected to the signal line M0. That is, by raising the layer of the signal line to an upper layer once, the signal line is diverted and voltage can be supplied to, for example, an MOS transistor, which is a target destination. When this is expressed in a circuit diagram, it is as illustrated in FIG. 16C.

### Effects According to Second Embodiment

In the case of the nonvolatile semiconductor device according to the second embodiment, in addition the above-described effects (1)-(5), the following effect (6) can be obtained.

(6) A spare signal path can be efficiently created.
In the case of the nonvolatile semiconductor device according to the second embodiment, as described above, in the plane formed by the first direction and the second direction, a distance exists between an outer edge of the template TM and the insulating film DY with respect to any side of the insulating film DY. In this way, since the insulating film DY is arranged in advance in a predetermined position, it i easy to determine in which region in the template TM to form a spare wiring path.

Further, as described above, to form a spare signal line D1 that functions as an alternative path, only one mask is required to be modified. Therefore, the cost caused by forming the alternative path can be minimized.

### Third Embodiment

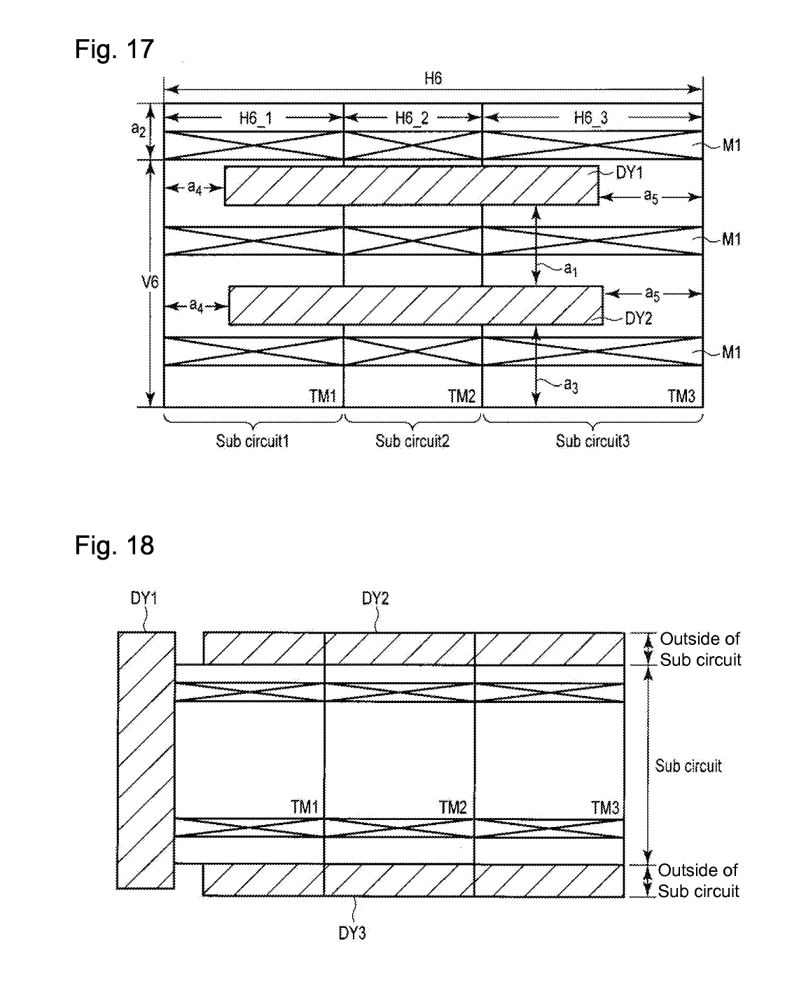

Next, a nonvolatile semiconductor device according to a third embodiment is explained using FIG. 17. In the above embodiments, examples are explained in which two or more insulating films DY (for example, insulating film DY1 and insulating film DY2) are arranged in a template TM. However, in some cases, one insulating film DY cannot be arranged in a template TM because the size of the template TM is small.

In the nonvolatile semiconductor device according to the third embodiment, when the size of each one template TM is small as described above, a plurality of such small templates TM are combined to form a large template TM, and thereafter, an insulating film DY is arranged in a manner traversing the plurality of templates TM.

<Plan View>

FIG. 17 illustrates a plan view of seventh template TM1-seventh template TM3 (Sub-Circuit1-SubCircuit3 in the drawing). The seventh template TM1-seventh template TM3 are respectively explained.

The seventh template TM1 has a height of V6 and a width of H6_1. The seventh template TM2 has a height of V6 and a width of H6_2. The seventh template TM3 has a height of V6 and a width of H6_3.

When these templates TM1-TM3 each have a small size, as illustrated in FIG. 17, these three templates TM are combined to form a large template TM having a height of V6 and a width of H6.

Further, as illustrated, in the seventh template TM-seventh template TM3, an insulating film DY1 and an insulating film DY2 are arranged. Specifically, the insulating films DY1 and DY2 are arranged in such a manner that the above formula (1) or formula (2) i satisfied. That is, letting the distances between the outer edges of the template TM and the insulating films DY1 and DY2 be a2, a3, a4 and a5 respectively and the distance between the insulating film DY1 and the insulating film DY2 be a1, the insulating films DY1 and DY2 are arranged in such a manner that the coverage of the insulating films DY1 and DY2 with respect to the template TM is above a minimum coverage.

In the third embodiment, the seventh template TM1-seventh template TM3 are arranged along the x-direction. However, the template may also be configured by arranging the seventh template TM1-seventh template TM3 along the y-direction.

### Modified Embodiment

Next, a modified example according to the nonvolatile semiconductor device of the third embodiment is explained using FIG. 18. In this modified example, an example of a case is explained where an insulating film DY cannot be arranged in a template TM even when a plurality of templates TM are combined.

<Plan View>

FIG. 18 illustrates a plan view of eighth template TM1-eighth template TM3. Even when the eighth template TM 1-eighth template TM3 are combined, an insulating film DY still cannot be arranged in a manner traversing these templates TM. In this case, insulating films DY1-DY3 are arranged outside these templates TM.

Even in the case of such an arrangement, the insulating films DY1-DY3 are arranged in a manner that the above formula (1) or formula (2) is satisfied.

In the above, the first-third embodiments and the modified example of the third embodiment are explained with reference to the drawings. The templates TM according to all of these embodiments and the modified example may be incorporated in one semiconductor chip. That is, a set of templates TM is illustrated in FIG. 6. Among these templates TM, the various templates TM explained in the above may also be incorporated.

In the above embodiments, the width H, height V and arrangement position of an insulating film DY are respectively set in a manner that the minimum coverage x_min is satisfied. However, when the minimum coverage x_min can be satisfied by varying, for example, the width H of the insulating film DY, there is no need to set other parameters (for example, the height V, the arrangement position, and the like). The same applies to the height V and the arrangement position of the insulating film DY.

Further, the above embodiments are explained using the insulating films DY each having a shape of a cuboid as an example. However, as far as a region for arranging a contact plug CP is sufficiently provided while the minimum coverage of the insulating film DY with respect to the template TM is satisfied, the shape of the insulating film DY is not limited to that of a cuboid, but may also be that of a cylinder and other shapes.

While certain embodiments have been described, these embodiments have been presented by way of example only; and are not intended to limit the scope of the inventions. Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirits of the inventions.

The structure of the memory cell array is not limited as above description. A memory cell array formation may be as disclosed in U.S. patent application Ser. No. 12/532,030, the entire contents of which are incorporated by reference herein.

What is claimed is:

1. A nonvolatile semiconductor memory device, comprising:
a first region in which a memory cell array having a plurality of memory cells arrayed in three dimensions has been formed; and
a second region in which a peripheral circuit for controlling the memory cell array has been formed, the peripheral circuit including an insulating film and a template region, wherein the template region has a length of V1 in a first direction and a length of H1 in a second direction which is generally perpendicular to the first direction, the insulating film has a length of DY_V1 in the first direction and a length of DY_H1 in the second direction, no edge of the insulating film and the template region overlap and the insulating film is arranged in the template region in such a manner that a coverage ratio of the insulating film with respect to the template region is equal to or above a coverage ratio of 30-50%.

2. The nonvolatile semiconductor memory device according to claim 1, further comprising:
an MOS transistor including a control gate and an impurity diffusion layer under the memory cell array and the peripheral circuit;
a power source line arranged in the second region and supplying a voltage to the MOS transistor; and
a contact plug between any one side of the insulating film and an edge of the second region, the contact plug electrically connected via the power source line to one of the impurity diffusion layer and the control gate.

3. The nonvolatile semiconductor memory device according to claim 2, wherein
the second region is comprises a plurality of template regions, and
the power source line crosses the plurality of template regions.

4. The nonvolatile semiconductor memory device according to claim 2, wherein
the peripheral circuit comprises a plurality of the second regions.

5. The nonvolatile semiconductor memory device according to claim 3, wherein
the peripheral circuit comprises a plurality of the second regions.

6. The nonvolatile semiconductor memory device according to claim 1, wherein
the second region includes:
a well region of a first conductivity type formed in a semiconductor substrate and a MOS transistor is formed in the first well region, and
a well region of a second conductivity type that is different from first conductivity type surrounding the second region.

7. The nonvolatile semiconductor memory device according to claim 2, wherein
the second region includes:
a well region of a first conductivity type formed in a semiconductor substrate and the MOS transistor is formed in the first well region, and
a well region of a second conductivity type that is different the first conductivity type surrounding the second region.

8. A nonvolatile semiconductor memory device, comprising:
a first region in which a memory cell array having a plurality of memory cells arrayed in three dimensions has been formed; and
a second region in which a peripheral circuit for controlling the memory cell array has been formed, the peripheral circuit including one or more insulating film and a template region, and a contact plug electrically connecting a lower metal layer to an upper metal layer;
wherein a thickness of the one or more insulation film is approximately the same as a thickness of the memory cell array,
a coverage ratio of the one or more insulations film within the template region is equal to or greater than a coverage ratio of 30-50%, and
the contact plug is located within the template region in an area not covered by the one or more insulation film.

9. The nonvolatile memory device of claim 8, wherein the template region is a rectangle.

10. The nonvolatile memory device of claim 9, wherein two insulation films are in the template region.

11. The nonvolatile memory device of claim 10, wherein the contact plug is between the two insulation films.

12. The nonvolatile memory device of claim 9, further comprising a plurality of contact plugs.

13. The nonvolatile memory device of claim 8, wherein the one or more insulation film is a cuboid.

14. The nonvolatile memory device of claim 8, wherein the template region is a rectangle and the one or more insulation film is a cuboid.

15. The nonvolatile memory device of claim 8, wherein the template region includes a guard ring.

16. The nonvolatile memory device of claim 8, wherein each insulation film in the template region has a same dimension.

17. A nonvolatile memory device, comprising:
a first region in which a memory cell array having a plurality of memory cells arrayed in three dimensions has been formed; and
a second region in which a peripheral circuit for controlling the memory cell array has been formed, the peripheral circuit including a plurality of insulating films and a plurality of template regions, and a plurality of contact plugs electrically connecting a lower metal layer to an upper metal layer;
wherein a thickness of each insulation film is approximately the same as a thickness of the memory cell array,
a coverage ratio of the insulation films within each template region is equal to or greater than a coverage ratio of 30-50%,
at least one contact plug of the plurality of contact plugs is located within the template region in an area not covered by the insulation films,
the template regions are rectangular, and
the insulation films within the template regions are spaced from each other by at least a distance sufficient to allow one of the contact plugs to be placed between adjacent insulation films.

18. The nonvolatile memory device of claim 17, wherein all the template regions are a first same size.

19. The nonvolatile memory device of claim 18, wherein all the insulation films are a second same size.

20. The nonvolatile memory device of claim 17, wherein an insulation films overlaps portions of two or more template regions which have been combined, and the coverage ratio is calculated with respect to the combined two or more template regions.
